(19) United States
(12) Patent Application Publication
(10) Pub. No.: US 2023/0329118 A1
(43) Pub. Date: Oct. 12, 2023

(54) PIEZOELECTRIC DRIVING ELEMENT

(71) Applicant: Panasonic Intellectual Property Management Co., Ltd., Osaka (JP)

(72) Inventor: Kazuki KOMAKI, Osaka (JP)

(21) Appl. No.: 18/210,541

(22) Filed: Jun. 15, 2023

Related U.S. Application Data
(63) Continuation of application No. PCT/JP2021/042775, filed on Nov. 22, 2021.

(30) Foreign Application Priority Data
Dec. 18, 2020 (JP) 2020-209955

(51) Int. Cl. H10N 30/20; H10N 30/06; H10N 30/097

(52) U.S. Cl. CPC H10N 30/2042; H10N 30/06; H10N 30/097

(57) ABSTRACT

A piezoelectric driving element is a cantilever-type piezoelectric driving element in which one end which is a fixed end is fixed to a support base and another end which is a free end is driven. The piezoelectric driving element includes: a first piezoelectric body disposed on the fixed end side; and a second piezoelectric body disposed on the free end side with respect to the fixed end. Here, a thickness of the second piezoelectric body is set to be smaller than a thickness of the first piezoelectric body.

### CROSS REFERENCE TO RELATED APPLICATION

This application is a continuation of International Application No. PCT/JP2021/042775 filed on Nov. 22, 2021, entitled “PIEZOELECTRIC DRIVING ELEMENT”, which claims priority under 35 U.S.C. Section 119 of Japanese Patent Application No. 2020-209955 filed on Dec. 18, 2020, entitled “PIEZOELECTRIC DRIVING ELEMENT”. The disclosures of the above applications are incorporated herein by reference.

### BACKGROUND OF THE INVENTION

### Field of the Invention

The present invention relates to a piezoelectric driving element that drives a to-be-driven body by a driving force generated from a piezoelectric body.

### Description of Related Art

In recent years, piezoelectric driving elements that drive a to-be-driven body by a driving force generated from a piezoelectric body have been used in various devices. For example, a light deflector for deflecting light is configured by providing a reflection surface on a to-be-driven body. Also, a microswitch is configured by providing an electrode for opening and closing two terminals, on a to-be-driven body.

In these devices, a so-called cantilever-type piezoelectric driving element can be used. In the cantilever-type piezoelectric driving element, one end (fixed end) is fixed to a support base, and a to-be-driven body is disposed at another end (free end). In this configuration, it is required to increase the amount of displacement of the free end while increasing a force generated at the free end (hereinafter, referred to as “generated force”), and it is also required to increase the resonance frequency of the element according to the driving usage.

Japanese Patent No. 6051412 describes a configuration in which the amount of displacement of a free end can be increased by stacking vibration plates made of a plurality of materials on a piezoelectric body. Also, Japanese Patent No. 4413873 describes a configuration in which the total amount of displacement of a free end can be increased by disposing a plurality of piezoelectric layers and electrode layers.

In each of the configurations described in Japanese Patent No. 6051412 and Japanese Patent No. 4413873 above, the amount of displacement of the free end can be increased, but the amount of displacement of the free end, the generated force at the free end, and the resonance frequency cannot be increased together. In general, the amount of displacement of the free end, the generated force at the free end, and the resonance frequency of the element have a trade-off relationship with each other. For example, if the piezoelectric body is lengthened, the amount of displacement of the free end increases, but the generated force at the free end and the resonance frequency of the element decrease. In addition, if the thickness of the piezoelectric body is increased, the generated force at the free end and the resonance frequency of the element increase, but the amount of displacement of the free end decreases.

### SUMMARY OF THE INVENTION

A main aspect of the present invention is directed to a cantilever-type piezoelectric driving element in which one end which is a fixed end is fixed to a support base and another end which is a free end is driven. The piezoelectric driving element according to this aspect includes: a first piezoelectric body disposed on the fixed end side; and a second piezoelectric body disposed on the free end side with respect to the fixed end. Here, a thickness of the second piezoelectric body is set to be smaller than a thickness of the first piezoelectric body.

In the driving element according to this aspect, since the thickness of the second piezoelectric body on the free end side is smaller, the mass of a portion at and near the free end is decreased, so that the resonance frequency of the element can be increased while the amount of displacement of the free end is kept large. In addition, since the portion at and near the free end is driven by the second piezoelectric body, the amount of displacement of and the generated force at the free end can be increased as compared to those in the case with only the first piezoelectric body. Therefore, in the piezoelectric driving element according to this aspect, the amount of displacement of and the generated force at the free end and the resonance frequency can all be increased.

The effects and the significance of the present invention will be further clarified by the description of the embodiments below. However, the embodiments below are merely examples for implementing the present invention. The present invention is not limited by the description of the embodiments below in any way.

### BRIEF DESCRIPTION OF THE DRAWINGS

FIG. 1 is a perspective view showing a configuration of a piezoelectric driving element according to Embodiment 1;

FIG. 2A is a top view of the piezoelectric driving element according to Embodiment 1;

FIG. 2B is a cross-sectional view of the piezoelectric driving element according to Embodiment 1;

FIG. 3A to FIG. 3D are each a diagram illustrating a process for forming the piezoelectric driving element according to Embodiment 1;

FIG. 4A and FIG. 4B are perspective views showing configurations of piezoelectric driving elements according to comparative examples, respectively;

FIG. 5 is a perspective view showing a configuration of a piezoelectric driving element according to Embodiment 2;

FIG. 6A is a top view of the piezoelectric driving element according to Embodiment 2;

FIG. 6B is a cross-sectional view of the piezoelectric driving element according to Embodiment 2;

FIG. 7A is a top view showing a configuration of a piezoelectric driving element according to a modification of Embodiment 2;

FIG. 7B is a cross-sectional view showing a configuration of a piezoelectric driving element according to another modification of Embodiment 2;

FIG. 8 is a perspective view showing a configuration of a piezoelectric driving element according to Embodiment 3;

FIG. 9A and FIG. 9B are a top view and a bottom view of the piezoelectric driving element according to Embodiment 3, respectively;

FIG. 10A and FIG. 10B are each a cross-sectional view of the piezoelectric driving element according to Embodiment 3;

FIG. 11 is a perspective view showing a configuration of a piezoelectric driving element according to Embodiment 4;

FIG. 12 is a perspective view showing a configuration of a piezoelectric driving element according to Embodiment 5;

FIG. 13 is a perspective view showing another configuration of the piezoelectric driving element according to Embodiment 5;

FIG. 14A to FIG. 14C are each a cross-sectional view of a piezoelectric driving element according to Embodiment 6; and

FIG. 15A and FIG. 15B are each a cross-sectional view of a piezoelectric driving element according to a modification.

It should be noted that the drawings are solely for description and do not limit the scope of the present invention by any degree.

### DETAILED DESCRIPTION

Hereinafter, embodiments of the present invention will be described with reference to the drawings. For convenience, in each drawing, X, Y, and Z axes that are orthogonal to each other are additionally shown. The X-axis direction is the length direction of a piezoelectric body, and the Y-axis direction and the Z-axis direction are the width direction and the thickness direction of the piezoelectric body, respectively. The X-axis direction is also a direction connecting a fixed end and a free end of a piezoelectric driving element.

### Embodiment 1

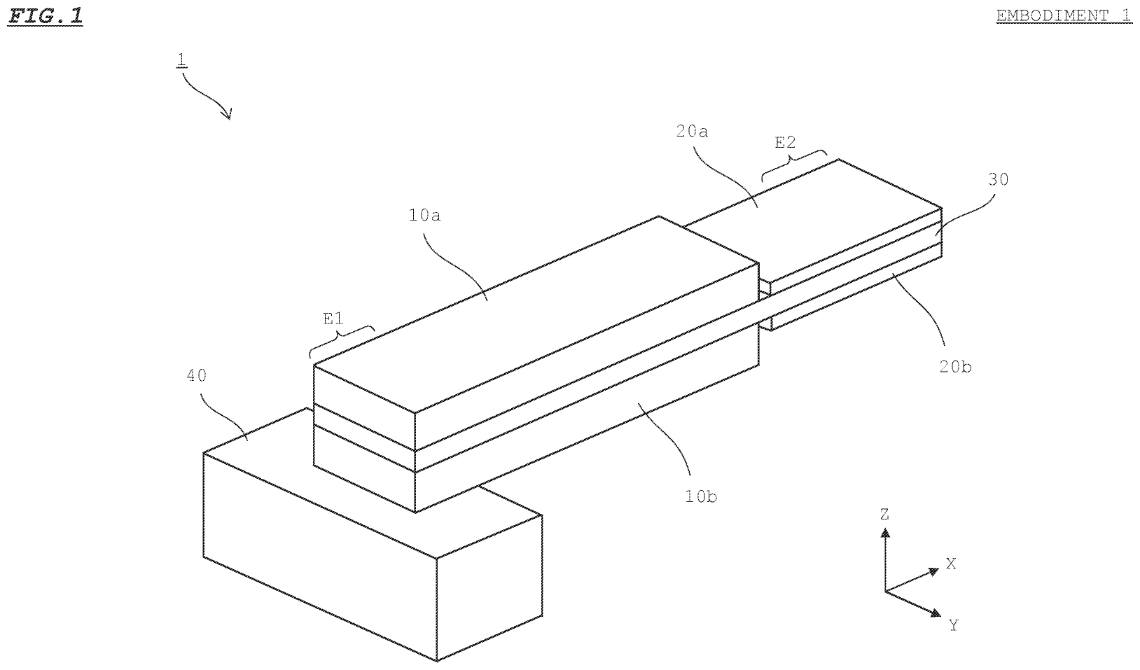

FIG. 1 is a perspective view showing a configuration of a piezoelectric driving element 1 according to Embodiment 1.

The piezoelectric driving element 1 includes first piezoelectric bodies 10a and 10b, second piezoelectric bodies 20a and 20b, a shim material 30, and a support base 40. The shim material 30 is made of, for example, a metal material such as copper (Cu), silicon, resin, ceramics made of an oxide, or the like, and the first piezoelectric bodies 10a and 10b and the second piezoelectric bodies 20a and 20b are disposed on the upper surface and the lower surface of the shim material 30, respectively. Here, the shim material 30 is a member that converts expansion and contraction of the first piezoelectric bodies 10a and 10b and the second piezoelectric bodies 20a and 20b in the X-axis direction into bending in the Z-axis direction, maintains a predetermined length against the expansion and contraction of the first piezoelectric bodies 10a and 10b and the second piezoelectric bodies 20a and 20b in the X-axis direction, and has flexibility that permits the bending in the Z-axis direction.

A structure composed of the first piezoelectric bodies 10a and 10b, the second piezoelectric bodies 20a and 20b, and the shim material 30 is fixed to the support base 40 at a fixed end E1 which is one end portion in the length direction. The first piezoelectric bodies 10a and 10b are disposed on the fixed end E1 side, and the second piezoelectric bodies 20a and 20b are disposed on a free end E2 side which is a side opposite to the fixed end E1.

By a driving voltage, the first piezoelectric bodies 10a and 10b and the second piezoelectric bodies 20a and 20b are caused to expand and contract in the X-axis direction, thereby driving the free end E2 in the Z-axis direction. That is, when, by a driving voltage, the first piezoelectric body 10a and the second piezoelectric body 20a on the upper side are caused to contract in the X-axis direction, and the first piezoelectric body 10b and the second piezoelectric body 20b on the lower side are caused to expand in the X-axis direction, the free end E2 is displaced in the Z-axis positive direction. Similarly, when the first piezoelectric body 10a and the second piezoelectric body 20a on the upper side are caused to expand in the X-axis direction, and the first piezoelectric body 10b and the second piezoelectric body 20b on the lower side are caused to contract in the X-axis direction, the free end E2 is displaced in the Z-axis negative direction. A to-be-driven body such as a mirror or an electrode is disposed at the free end E2.

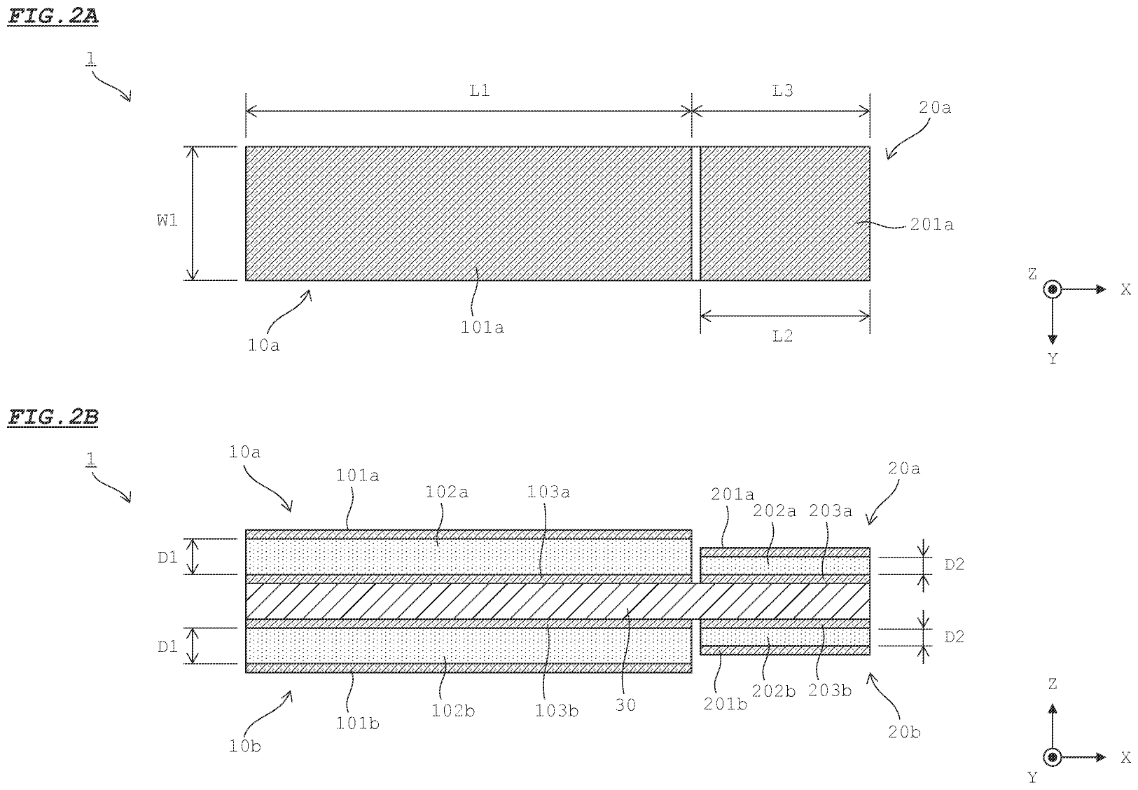

FIG. 2A is a top view of the piezoelectric driving element 1, and FIG. 2B is a cross-sectional view of the piezoelectric driving element 1. FIG. 2B shows a cross-section of the piezoelectric driving element 1 obtained by cutting the piezoelectric driving element 1 at a middle position in the Y-axis direction along a plane parallel to the X-Z plane.

The first piezoelectric body 10a on the upper side is configured by stacking an electrode layer 101a, a piezoelectric layer 102a, and an electrode layer 103a. Similarly, the first piezoelectric body 10b on the lower side is configured by stacking an electrode layer 101b, a piezoelectric layer 102b, and an electrode layer 103b. In addition, the second piezoelectric body 20a on the upper side is configured by stacking an electrode layer 201a, a piezoelectric layer 202a, and an electrode layer 203a. Similarly, the second piezoelectric body 20b on the lower side is configured by stacking an electrode layer 201b, a piezoelectric layer 202b, and an electrode layer 203b.

The piezoelectric layers 102a, 102b, 201a, and 201b are made of, for example, a piezoelectric material having a high piezoelectric constant, such as lead zirconate titanate (PZT). The electrode layers 101a, 103a, 101b, 103b, 201a, 203a, 201b, and 203b are made of a material having low electrical resistance and high heat resistance, such as silver (Ag) and platinum (Pt). The first piezoelectric body 10a on the upper side is disposed by forming a layer structure composed of the piezoelectric layer 102a and the upper and lower electrode layers 101a and 103a, on the upper surface of the shim material 30. The first piezoelectric body 10b on the lower side and the upper and lower second piezoelectric bodies 20a and 20b are also formed in the same manner.

As shown in FIG. 2B, the thicknesses of the second piezoelectric bodies 20a and 20b are smaller than the thicknesses of the first piezoelectric bodies 10a and 10b. More specifically, a thickness D2 of each of the piezoelectric layers 202a and 202b included in the second piezoelectric bodies 20a and 20b is smaller than a thickness D1 of each of the piezoelectric layers 102a and 102b included in the first piezoelectric bodies 10a and 10b. For example, the thickness D2 can be set to be about ⅕ of the thickness D1. As an example, the thickness D1 is set to about 250 μm, and the thickness D2 is set to about 50 μm. The thicknesses of all the electrode layers are equal to each other.

As shown in FIG. 2A, a length L1 of each of the first piezoelectric bodies 10a and 10b is longer than a length L2 of each of the second piezoelectric bodies 20a and 20b. Between the first piezoelectric bodies 10a and 10b and the second piezoelectric bodies 20a and 20b, there is a gap corresponding to the difference between the length L2 and a length L3 of a portion, of the shim material 30, on the free end E2 side with respect to the first piezoelectric bodies 10a and 10b. The first piezoelectric bodies 10a and 10b and the second piezoelectric bodies 20a and 20b have the same width Wl.

The displacement of the free end E2 shown in FIG. 1 is more influenced by driving by the first piezoelectric body 10a on the fixed end E1 side than by driving by the second piezoelectric body 20a on the free end E2 side. In order to suppress a decrease in the amount of displacement of the free end E2, the length L1 of each of the first piezoelectric bodies 10a and 10b is preferably not smaller than the length L2 of each of the second piezoelectric bodies 20a and 20b. In addition, in order to increase the generated force at the free end E2 as much as possible by a driving force from the second piezoelectric bodies 20a and 20b, a difference ΔL between the length L2 and the length L3 is preferably as small as possible. For example, the length L1 can be set to a length that is about four times the length L2, and the difference ΔL can be set to be about 1/10 of the length L2. As an example, the length L1 is set to about 20 mm, and the length L2 is set to about 5 mm. In addition, the difference ΔL is set to about 0.5 mm.

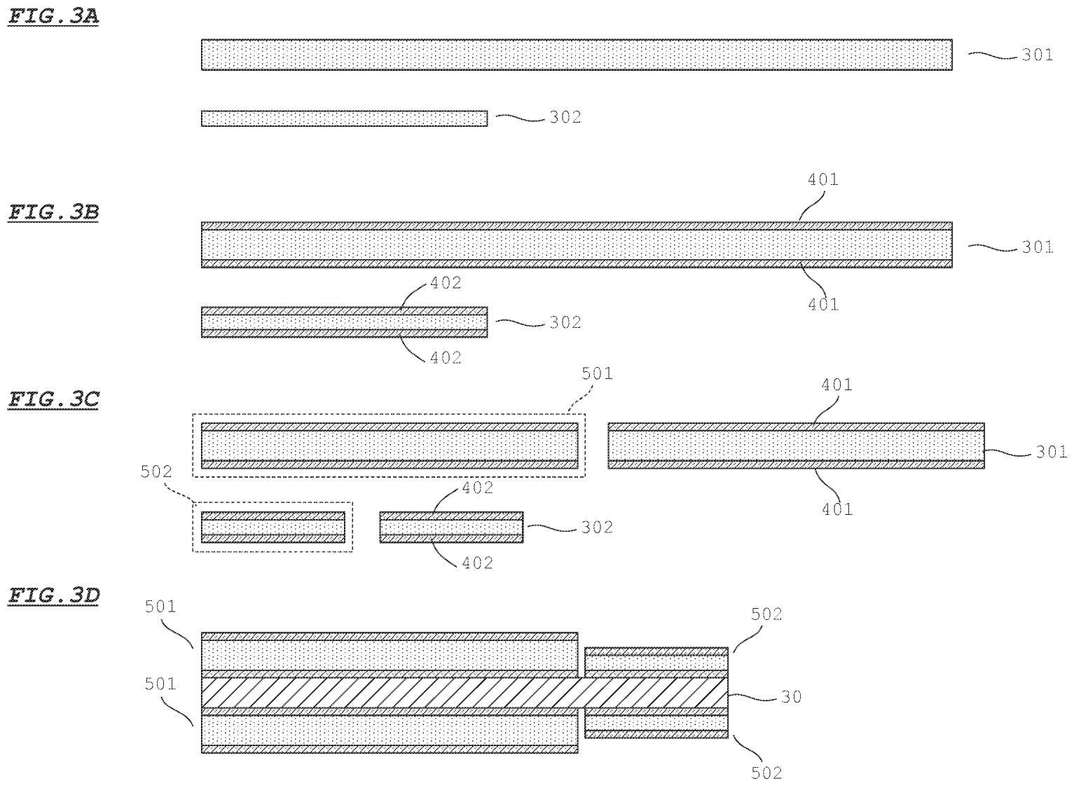

FIGS. 3A to 3D are each a diagram illustrating a process for forming the piezoelectric driving element 1.

The method for forming the piezoelectric driving element 1 is not particularly limited. For example, the piezoelectric driving element 1 may be formed by separately producing each component and then joining the components. In addition, the piezoelectric driving element 1 may be formed using the technology for manufacturing micro electric mechanical systems (MEMS).

As an example of the forming method, a process in which the piezoelectric driving element 1 is formed by separately producing each component and then joining the components is shown here.

First, as shown in FIG. 3A, PZT thin plates 301 and 302 are formed by press-molding and sintering ceramic powder containing Pb, Ti, and Zr. Next, as shown in FIG. 3B, Ag electrodes 401 and 402 are formed on the front and back surfaces of the PZT thin plates 301 and 302 by printing. Furthermore, the PZT thin plates 301 and 302 having the Ag electrodes 401 and 402 printed on the front and back surfaces thereof are diced into individual pieces to form structures 501 and 502 as shown in FIG. 3C. Then, the structures 501 and 502 are bonded to the front and back surfaces of the shim material 30 made of Cu, to form a structure shown in FIG. 3D. The structure in FIG. 3D is bonded to the upper surface of the support base 40 to form the piezoelectric driving element 1 in FIG. 1.

In the piezoelectric driving element 1 having the above configuration, the amount of displacement of and the generated force at the free end E2 and the resonance frequency of the element can all be increased. Hereinafter, this effect will be described in comparison with comparative examples.

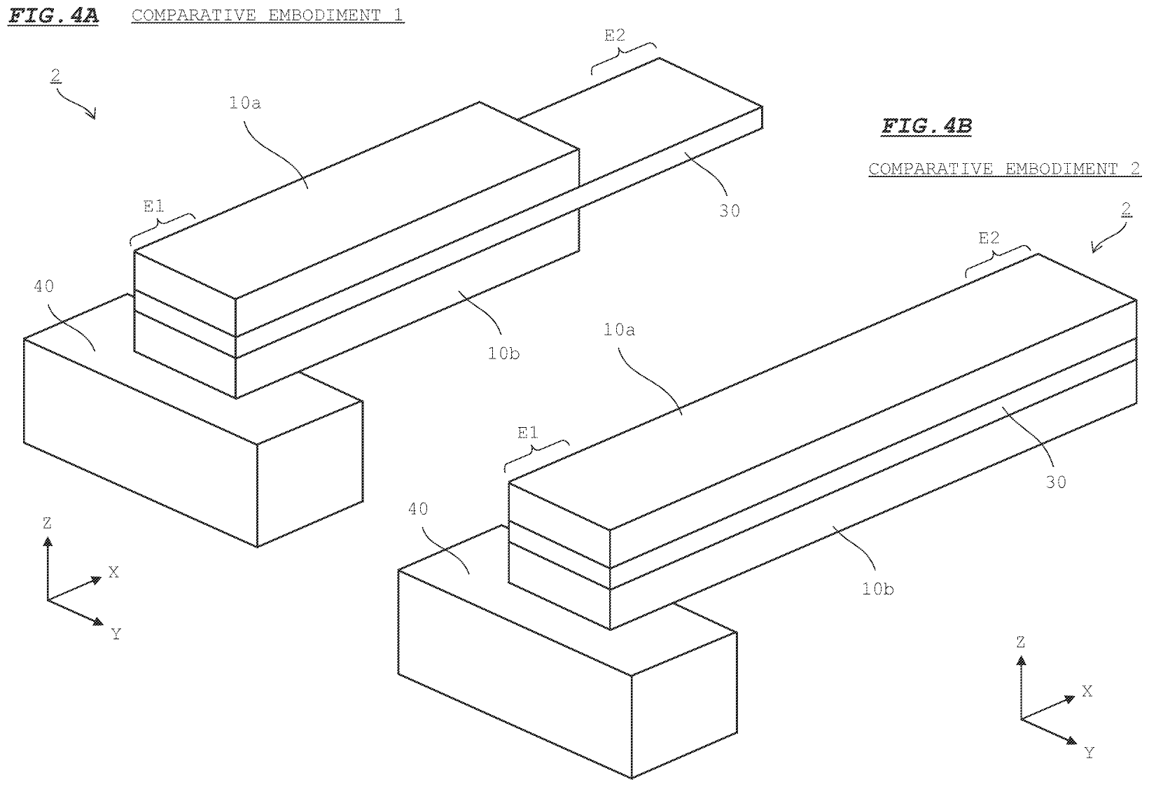

FIGS. 4A and 4B are perspective views showing configurations of piezoelectric driving elements 2 according to Comparative Examples 1 and 2, respectively.

Compared to the configuration in FIG. 1, the second piezoelectric bodies 20a and 20b are omitted in Comparative Example 1. That is, in the configuration of Comparative Example 1, on the free end E2 side with respect to the first piezoelectric bodies 10a and 10b, no piezoelectric body is disposed, and only the shim material 30 is left. In addition, in Comparative Example 2, the second piezoelectric bodies 20a and 20b shown in FIG. 1 are omitted, and the first piezoelectric bodies 10a and 10b extend to the distal end.

For the configuration of Comparative Example 1 and the configuration of Comparative Example 2, the inventor of the present invention examined the amount of displacement of and the generated force at the free end E2 and the resonance frequency by simulation.

In the examination, in each of Comparative Examples 1 and 2, the length in the X-axis direction of the fixed end E1 was set to 5 mm. In addition, in Comparative Example 2, the length in the X-axis direction of each of the first piezoelectric bodies 10a and 10b excluding the fixed end E1 was set to 26 mm, the thickness of each of the first piezoelectric bodies 10a and 10b was set to 0.3 mm, and the thickness of the shim material 30 was set to 0.1 mm. In Comparative Example 1, the length in the X-axis direction of a distal end portion at which the first piezoelectric bodies 10a and 10b were removed was set to 5 mm, and the length in the X-axis direction of each of the first piezoelectric bodies 10a and 10b excluding the fixed end E1 was set to 21 mm. The thickness of each of the first piezoelectric bodies 10a and 10b and the thickness of the shim material 30 in Comparative Example 1 were set to 0.3 mm and 0.1 mm, respectively, as in Comparative Example 2.

In the configuration of Comparative Example 2, when the first piezoelectric bodies 10a and 10b were driven at a predetermined voltage, the amount of displacement of the free end E2 was 128 μm, and the resonance frequency of the free end E2 was 525 Hz. Meanwhile, in the configuration of Comparative Example 1, when the first piezoelectric bodies 10a and 10b were driven at the same voltage, the amount of displacement of the free end E2 was 122 μm, and the resonance frequency of the free end E2 was 725 Hz. Thus, in the configuration of Comparative Example 1, by removing the first piezoelectric bodies 10a and 10b at the distal end portion, the resonance frequency of the element was significantly increased while the amount of displacement of the free end E2 was maintained to be substantially the same amount.

However, in the configuration of Comparative Example 1, since there is no piezoelectric body at the distal end portion, the generated force at the free end E2 is decreased.

On the other hand, in the configuration in FIG. 1, since the second piezoelectric bodies 20a and 20b are disposed on the free end E2 side, the generated force at the free end E2 is increased by the driving force generated from the second piezoelectric bodies 20a and 20b, while the rigidity of the free end E2 is increased. In addition, in the configuration in FIG. 1, since the thickness of each of the second piezoelectric bodies 20a and 20b is smaller than the thickness of each of the first piezoelectric bodies 10a and 10b, a significant decrease in the resonance frequency of the free end E2 due to the second piezoelectric bodies 20a and 20b being disposed is suppressed. Therefore, in the configuration in FIG. 1, the resonance frequency of the element can be increased while the amount of displacement of and the generated force at the free end E2 are kept large.

The thickness of each of the second piezoelectric bodies 20a and 20b is set to a thickness that allows a significant decrease in the amount of displacement of and the resonance frequency at the free end E2 to be suppressed while increasing the generated force at the free end E2. From this viewpoint, the thickness D2 of each of the second piezoelectric bodies 20a and 20b is preferably set to be about ⅕ of the thickness D1 of each of the first piezoelectric bodies 10a and 10b. As an example, the thickness D1 of each of the first piezoelectric bodies 10a and 10b can be set to about 250 μm, and the thickness D2 of each of the second piezoelectric bodies 20a and 20b can be set to about 50 μm.

### Effects of Embodiment 1

According to Embodiment 1 described above, the following effects are achieved.

Since the thicknesses of the second piezoelectric bodies 20a and 20b on the free end E2 side are smaller as shown in FIG. 1 and FIG. 2B, the mass of a portion at and near the free end E2 is decreased, so that the resonance frequency of the free end E2 can be increased while the amount of displacement of the free end E2 is kept large. In addition, since the portion at and near the free end E2 is driven by the second piezoelectric bodies 20a and 20b, the amount of displacement of and the generated force at the free end E2 can be increased as compared to those in the case with only the first piezoelectric bodies 10a and 10b. Therefore, the resonance frequency of the element can be increased while the amount of displacement of and the generated force at the free end E2 are kept large.

Since the first piezoelectric bodies 10a and 10b and the second piezoelectric bodies 20a and 20b are disposed on both of the upper and lower sides of the shim material 30 as shown in FIG. 1, the driving forces by the piezoelectric bodies can be increased. Accordingly, the amount of displacement of and the generated force at the free end E2 can be effectively increased.

### Embodiment 2

In Embodiment 1 described above, one second piezoelectric body 20a and one second piezoelectric body 20b are disposed on the upper and lower surfaces of the shim material 30, respectively, but in Embodiment 2, two second piezoelectric bodies are disposed on each of the upper and lower surfaces of the shim material 30.

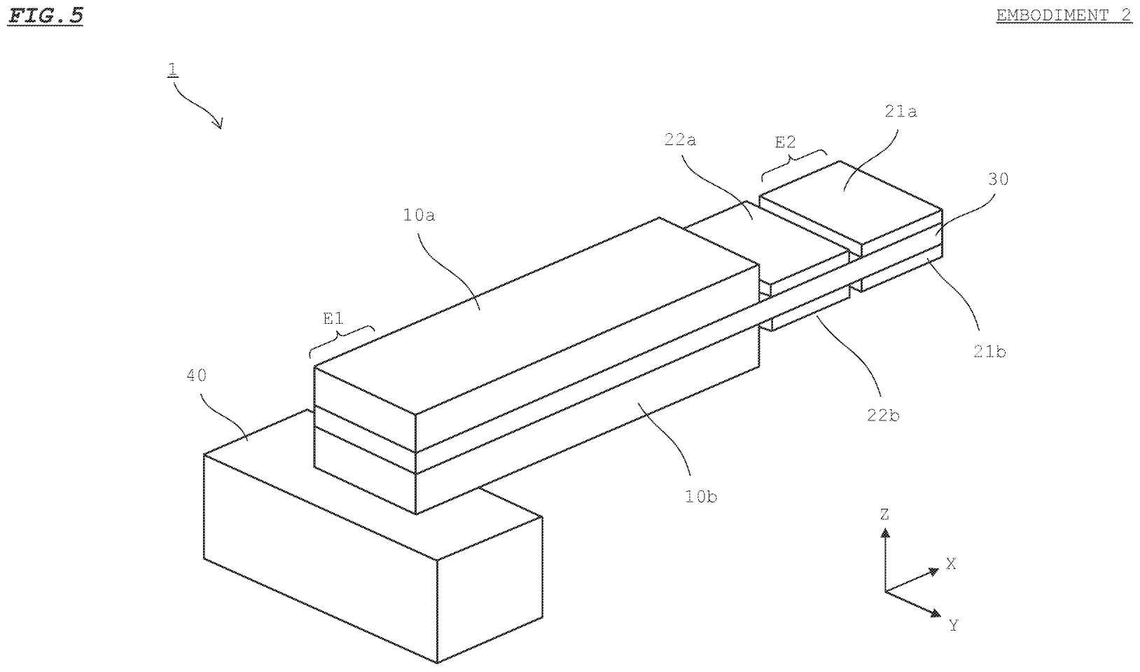

FIG. 5 is a perspective view of a configuration of the piezoelectric driving element 1 according to Embodiment 2.

As shown in FIG. 5, in Embodiment 2, second piezoelectric bodies 21a and 22a on the upper side are disposed on the upper surface of the shim material 30 so as to be aligned in a direction (X-axis direction) from the fixed end E1 toward the free end E2, and second piezoelectric bodies 21b and 22b on the lower side are disposed on the lower surface of the shim material 30 so as to be aligned in the direction (X-axis direction) from the fixed end E1 toward the free end E2. The lengths of the second piezoelectric bodies 21a and 21b in the X-axis direction are equal to each other, and the lengths of the second piezoelectric bodies 22a and 22b in the X-axis direction are equal to each other. Gaps are provided between the second piezoelectric bodies 21a and 21b and the second piezoelectric bodies 22a and 22b, and gaps are provided between the second piezoelectric bodies 22a and 22b and the first piezoelectric bodies 10a and 10b. The configurations of the first piezoelectric bodies 10a and 10b are the same as in Embodiment 1 described above.

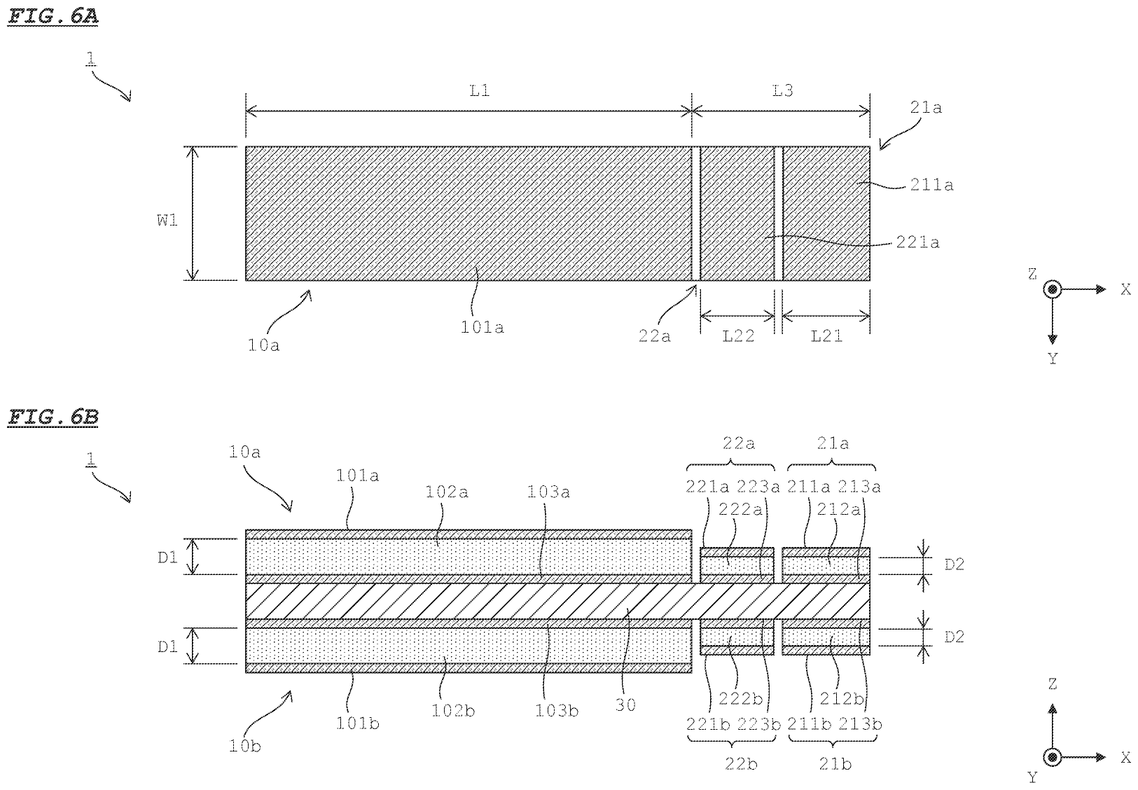

FIG. 6A is a top view of the piezoelectric driving element 1 according to Embodiment 2, and FIG. 6B is a cross-sectional view of the piezoelectric driving element 1 according to Embodiment 2. FIG. 6B shows a cross-section of the piezoelectric driving element 1 obtained by cutting the piezoelectric driving element 1 at a middle position in the Y-axis direction along a plane parallel to the X-Z plane.

Similar to the second piezoelectric bodies 20a and 20b in Embodiment 1 described above, the second piezoelectric body 21a is configured by stacking electrode layers 211a and 213a above and below a piezoelectric layer 212a, respectively, and the second piezoelectric body 21b is configured by stacking electrode layers 211b and 213b above and below a piezoelectric layer 212b, respectively. Similarly, the second piezoelectric body 22a is configured by stacking electrode layers 221a and 223a above and below a piezoelectric layer 222a, respectively, and the second piezoelectric body 22b is configured by stacking electrode layers 221b and 223b above and below a piezoelectric layer 222b, respectively.

The thickness D2 of each of the piezoelectric layers 212a, 212b, 222a, and 222b in the second piezoelectric bodies 21a, 21b, 22a, and 22b is smaller than the thickness D1 of each of the piezoelectric layers 102a and 102b of the first piezoelectric bodies 10a and 10b as in Embodiment 1 described above. The thicknesses of all the electrode layers are equal to each other. Therefore, the thickness of each of the second piezoelectric bodies 21a, 21b, 22a, and 22b is smaller than the thickness of each of the first piezoelectric bodies 10a and 10b.

The second piezoelectric bodies 21a, 21b, 22a, and 22b are formed on the upper surface or the lower surface of the shim material 30 by the same method as shown in FIGS. 3A to 3D in Embodiment 1 described above. In the process in FIG. 3B, the structure on the lower side of FIG. 3B is divided into four individual pieces according to the lengths of the second piezoelectric bodies 21a, 21b, 22a, and 22b. In the process in FIG. 3D, each of the four individualized structures is bonded at the corresponding position on the upper surface or the lower surface of the shim material 30. Thus, a structure shown in FIG. 6B is formed. As in Embodiment 1 described above, the method for forming the piezoelectric driving element 1 is not limited to this method.

In Embodiment 2, for example, the second piezoelectric bodies 21a and 21b on the distal end side are used for driving the free end E2, and the second piezoelectric bodies 22a and 22b on the proximal side are used for detecting strain of the free end E2. When the free end E2 is displaced in the Z-axis direction, one of the upper and lower second piezoelectric bodies 22a and 22b expands, and the other thereof contracts. At this time, the amount of electric charge corresponding to the amount of bending (amount of displacement) of the free end E2 can be detected by detecting electric charge generated in the piezoelectric layers 222a and 222b, at the electrode layers 221a, 223a, 221b, and 223b.

Thus, by using the second piezoelectric bodies 22a and 22b for strain detection, it is possible to monitor a signal corresponding to the amount of displacement of the free end E2 when the first piezoelectric bodies 10a and 10b and the second piezoelectric bodies 21a and 21b are driven. Accordingly, for example, feedback control, such as adjusting a voltage applied to the first piezoelectric bodies 10a and 10b and the second piezoelectric bodies 21a and 21b, such that the free end E2 is displaced in a target displacement amount, can be performed.

In this case, a length L21 in the X-axis direction of each of the second piezoelectric bodies 21a and 21b and a length L22 in the X-axis direction of each of the second piezoelectric bodies 22a and 22b are set to lengths that allow an appropriate force to be generated at the free end E2 by the second piezoelectric bodies 21a and 21b and that enable appropriate detection of a signal corresponding to the amount of displacement of the free end E2. To cause a force to be generated at the free end E2 more effectively by the second piezoelectric bodies 21a and 21b, the length L21 is preferably longer. From this viewpoint, the length L21 is preferably longer than the length L22.

### Effects of Embodiment 2

In Embodiment 2 as well, as in Embodiment 1 described above, since the thicknesses of the second piezoelectric bodies 21a, 21b, 22a, and 22b are smaller than the thicknesses of the first piezoelectric bodies 10a and 10b, the resonance frequency of the element can be increased while the amount of displacement of and the generated force at the free end E2 are kept large.

Additionally, in the configuration of Embodiment 2, the second piezoelectric bodies 22a and 22b can be used as monitoring elements for detection of strain corresponding to the amount of displacement of the free end E2. Accordingly, feedback control, such as adjusting a voltage applied to the first piezoelectric bodies 10a and 10b and the second piezoelectric bodies 21a and 21b, such that the amount of displacement of the free end E2 becomes a target displacement amount, can be performed.

As shown in FIG. 5 and FIGS. 6A and 6B, the second piezoelectric bodies 21a and 21b for driving the free end E2 are disposed in regions symmetrical in a direction (Y-axis direction) perpendicular to the direction (X-axis direction) from the fixed end E1 toward the free end E2. Accordingly, the free end E2 can be uniformly driven by the second piezoelectric bodies 21a and 21b for driving, so that twisting of the free end E2 can be suppressed.

As shown in FIG. 5 and FIGS. 6A and 6B, the second piezoelectric bodies 22a and 22b for detecting strain of the free end E2 are disposed in regions symmetrical in the direction (Y-axis direction) perpendicular to the direction (X-axis direction) from the fixed end E1 toward the free end E2. Since the second piezoelectric bodies 22a and 22b are uniformly disposed, without being non-uniformly distributed on one side in the Y-axis direction, as described above, twisting in the bending of the free end E2 due to the second piezoelectric bodies 22a and 22b becoming unbalanced loads can be suppressed. Therefore, the free end E2 can be satisfactorily displaced by the second piezoelectric bodies 21a and 22a for driving while strain of the free end E2 is detected by the second piezoelectric bodies 22a and 22b.

In the above, among the second piezoelectric bodies 21a and 21b and the second piezoelectric bodies 22a and 22b, the second piezoelectric bodies 22a and 22b are used for strain detection. However, the second piezoelectric bodies 21a and 21b may be used for detecting strain of the free end E2, and the second piezoelectric bodies 22a and 22b may be used for driving the free end E2.

### Modifications

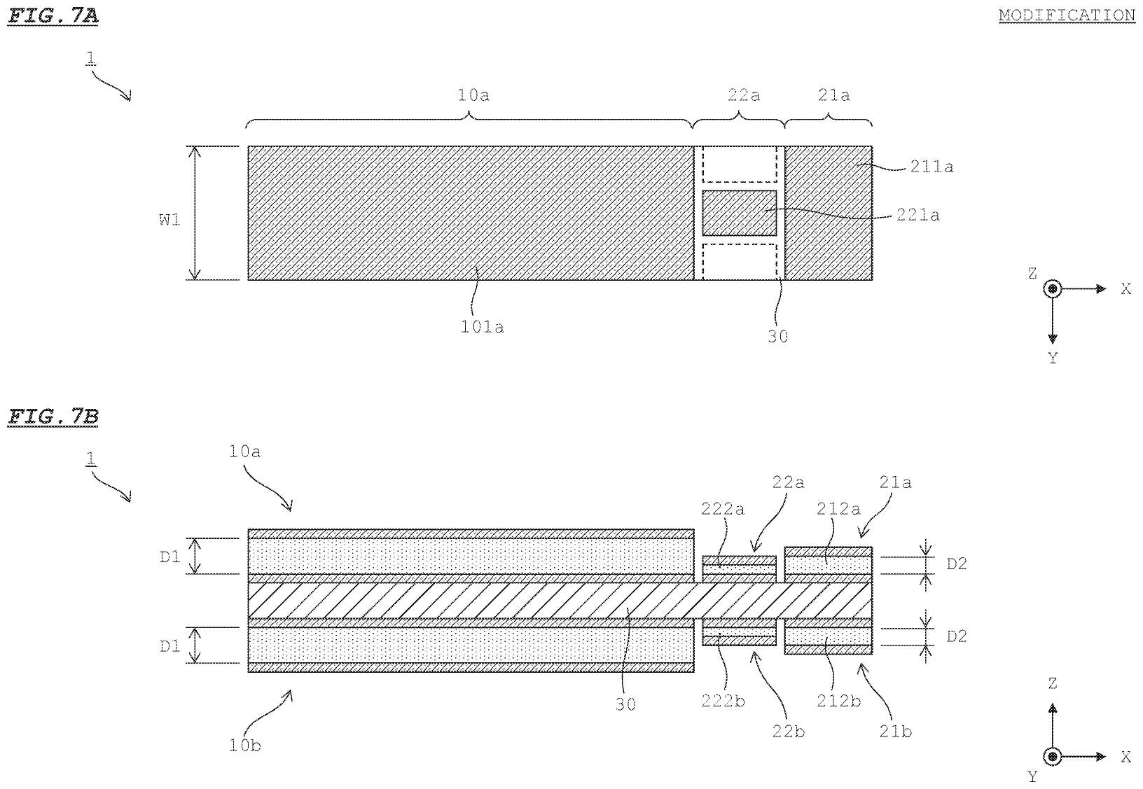

FIG. 7A is a top view showing a configuration of the piezoelectric driving element 1 according to a modification of Embodiment 2. For convenience, FIG. 7A shows a top view of the piezoelectric driving element 1, and the second piezoelectric body 22b disposed on the lower surface side of the piezoelectric driving element 1 also has the same configuration as the second piezoelectric body 22a on the upper surface side.

In this modification, the width in the Y-axis direction of each of the second piezoelectric bodies 22a and 22b is smaller than the width in the Y-axis direction of the shim material 30, that is, the width in the Y-axis direction of each of the second piezoelectric bodies 21a and 21b on the distal end side. The sizes of the upper and lower second piezoelectric bodies 22a and 22b are the same as each other. The second piezoelectric bodies 22a and 22b have a rectangular shape in a plan view, and are disposed at the center in the Y-axis direction.

In this modification as well, the second piezoelectric bodies 22a and 22b can be used as monitoring elements for detection of strain corresponding to the amount of displacement of the free end E2. In this case, as shown by broken lines in FIG. 7A, second piezoelectric bodies for driving may be further disposed on the Y-axis positive and negative sides of the second piezoelectric bodies 22a and 22b, respectively, so as to extend in the X-axis direction. Accordingly, as compared to the configuration of Embodiment 2, the generated force at the free end E2 can be increased.

In the configuration in FIG. 7A as well, the second piezoelectric bodies 22a and 22b for detecting strain corresponding to the amount of displacement of the free end E2 are disposed in regions symmetrical in the direction (Y-axis direction) perpendicular to the direction (X-axis direction) from the fixed end E1 toward the free end E2. Since the second piezoelectric bodies 22a and 22b are uniformly disposed, without being non-uniformly distributed on one side in the Y-axis direction, as described above, twisting in the bending of the free end E2 due to the second piezoelectric bodies 22a and 22b becoming unbalanced loads can be suppressed. Therefore, the free end E2 can be satisfactorily displaced by the second piezoelectric bodies 21a and 22a for driving while the amount of strain corresponding to the amount of displacement of the free end E2 is detected by the second piezoelectric bodies 22a and 22b.

FIG. 7B is a cross-sectional view showing a configuration of the piezoelectric driving element 1 according to another modification of Embodiment 2. Similar to FIG. 6B, FIG. 7B shows a cross-section of the piezoelectric driving element 1 obtained by cutting the piezoelectric driving element 1 at the center position thereof in the Y-axis direction.

In this modification, the thickness of each of the piezoelectric layers 222a and 222b of the second piezoelectric bodies 22a and 22b is smaller than the thickness D2 of each of the piezoelectric layers 212a and 212b of the second piezoelectric bodies 21a and 21b on the distal end side. The thicknesses of the upper and lower second piezoelectric bodies 22a and 22b are equal to each other. In addition, the thicknesses of the respective electrode layers of the second piezoelectric bodies 21a, 21b, 22a, and 22b are equal to each other. Therefore, the thicknesses of the second piezoelectric bodies 22a and 22b are smaller than the thicknesses of the second piezoelectric bodies 21a and 21b. The configurations of the second piezoelectric bodies 22a and 22b in a plan view are the same as in Embodiment 2.

In this modification as well, the second piezoelectric bodies 22a and 22b can be used as detection elements for monitoring the amount of strain corresponding to the amount of displacement of the free end E2. Here, in the case where the second piezoelectric bodies 21a, 21b, 22a, and 22b are all used as piezoelectric bodies for driving, as the thickness of any of the second piezoelectric bodies 21a, 21b, 22a, and 22b is increased, the generated force at the free end E2 in the piezoelectric driving element 1 can be increased, but the resonance frequency of the element is decreased. However, in this modification, the second piezoelectric bodies 22a and 22b which are used as elements for monitoring an amount of strain do not require a driving force, that is, a generated force, and only have to have a thickness or size required for electric charge detection. In this modification, since the second piezoelectric bodies 22a and 22b are smaller than those in Embodiment 2, the resonance frequency of the element can be increased while the ability to detect strain is ensured.

In the case where the thicknesses of the second piezoelectric bodies 22a and 22b are small as in the modification in FIG. 7B, the electrode layers and the piezoelectric layers included in the second piezoelectric bodies 22a and 22b can be formed on the upper and lower surfaces of the shim material 30 by a sputtering method using a metal mask. In this case, first, the second piezoelectric bodies 22a and 22b may be formed on the upper and lower surfaces of the shim material 30, and then the first piezoelectric bodies 10a and 10b and the second piezoelectric bodies 21a and 21b formed by the same process as in FIGS. 3A to 3C may be bonded to the upper and lower surfaces of the shim material 30.

Also, in the modification in FIG. 7B as well, as in FIG. 7A, the widths in the Y-axis direction of the second piezoelectric bodies 22a and 22b may be narrowed. In this case as well, second piezoelectric bodies for driving may be further disposed on the Y-axis positive and negative sides of the second piezoelectric bodies 22a and 22b, respectively, so as to extend in the X-axis direction.

### Embodiment 3

In Embodiment 2 described above, the second piezoelectric body is divided in the X-axis direction. On the other hand, in Embodiment 3, the second piezoelectric body is divided in the Y-axis direction.

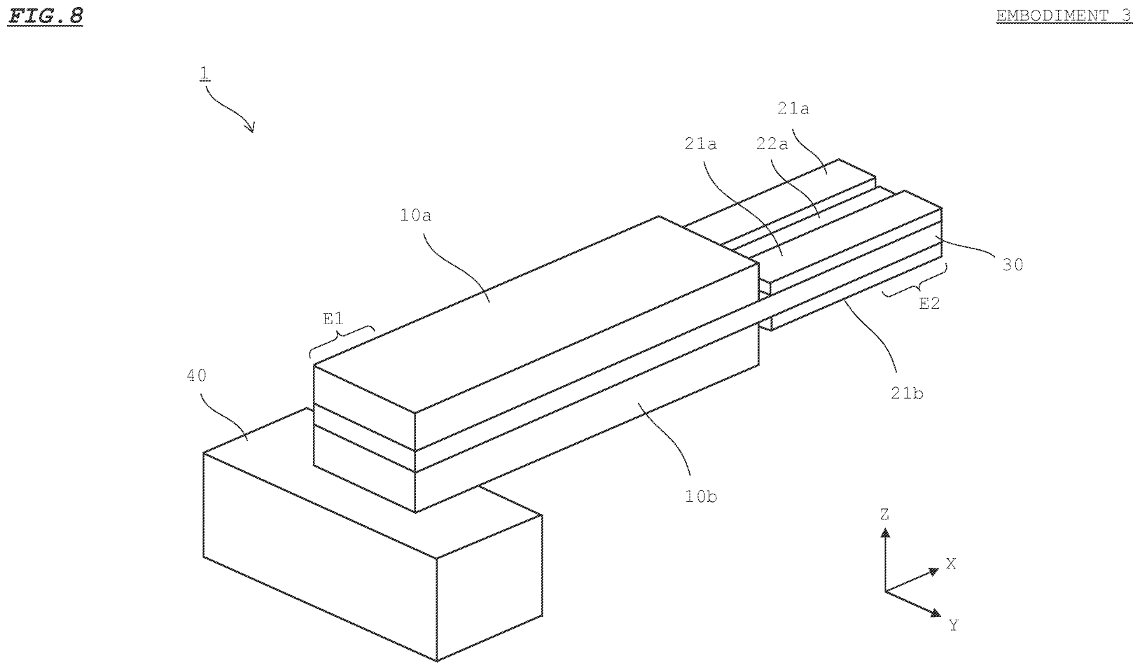

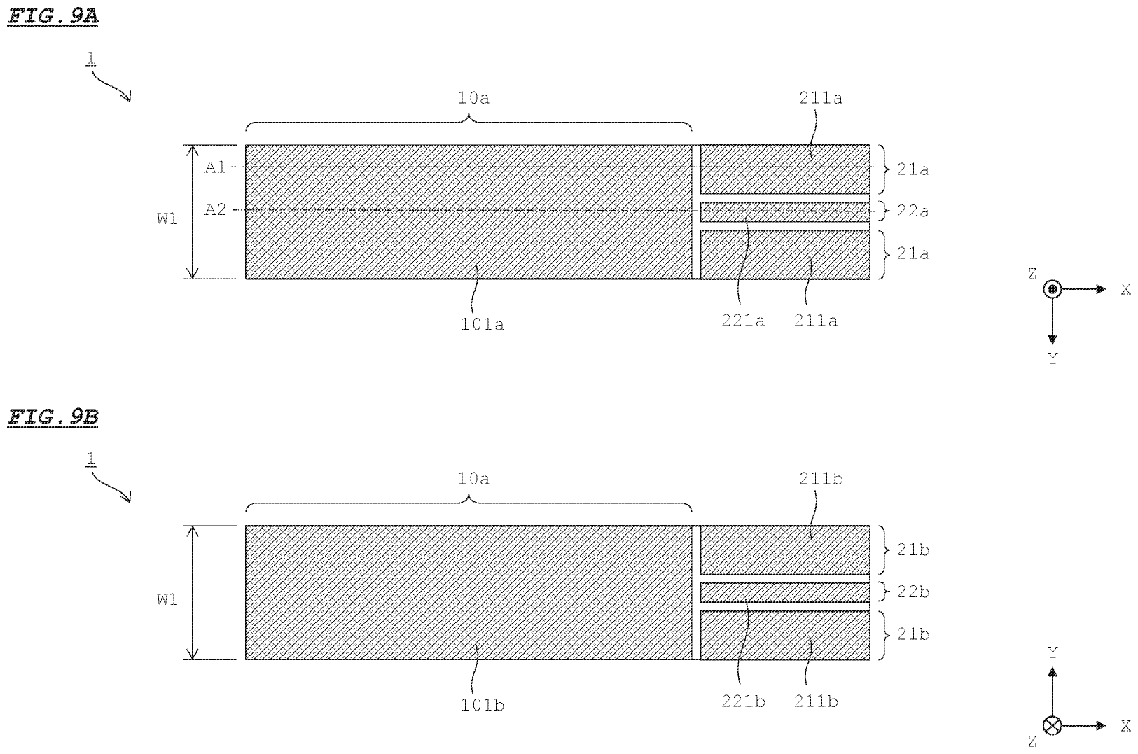

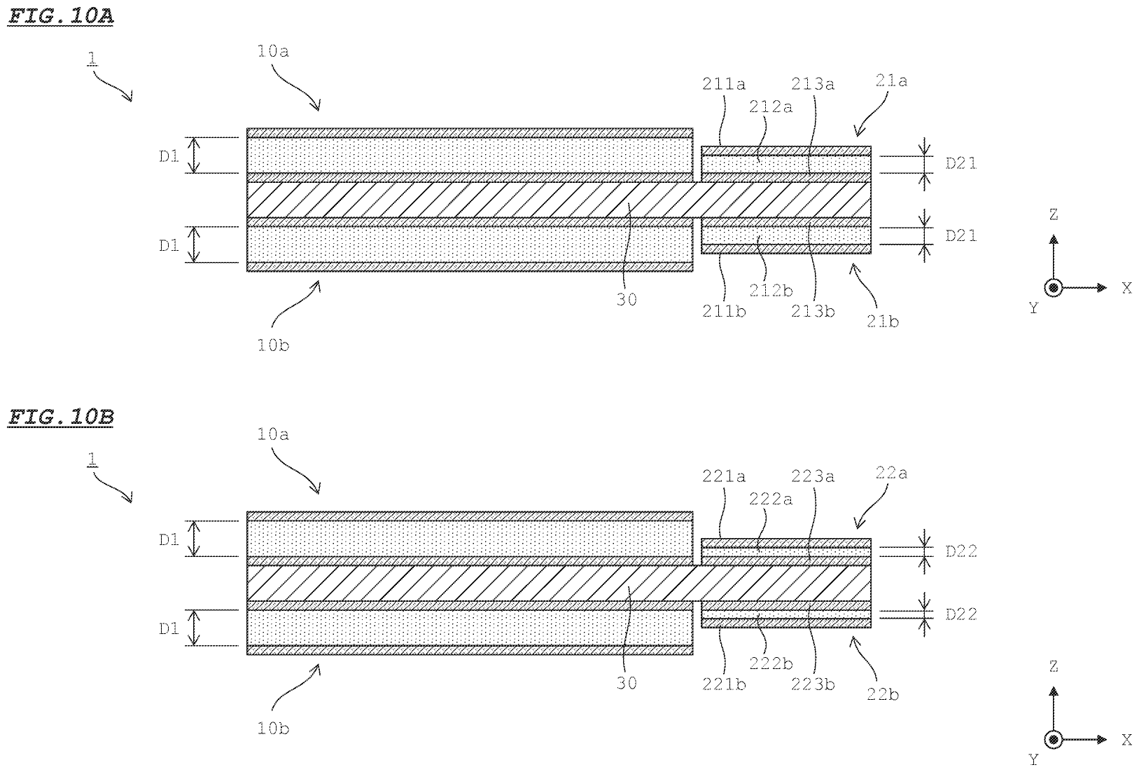

FIG. 8 is a perspective view showing a configuration of the piezoelectric driving element 1 according to Embodiment 3. FIGS. 9A and 9B are a top view and a bottom view of the piezoelectric driving element 1 according to Embodiment 3, respectively, and FIGS. 10A and 10B are each a cross-sectional view of the piezoelectric driving element 1 according to Embodiment 3. FIG. 10A shows a cross-sectional view of the piezoelectric driving element 1 taken at a position A1 in FIG. 9A, and FIG. 10B shows a cross-sectional view of the piezoelectric driving element 1 taken at a position A2 in FIG. 9A. A cross-sectional view taken at the position of the second piezoelectric body 21a on the Y-axis positive side is the same as FIG. 10A.

As shown in FIG. 8 to FIG. 10B, in Embodiment 3, the second piezoelectric body is divided in the Y-axis direction. That is, a plurality of second piezoelectric bodies are disposed so as to be aligned in a direction (Y-axis direction) intersecting the direction from the fixed end E1 toward the free end E2. On the free end E2 side of the piezoelectric driving element 1, the second piezoelectric bodies 22a and 22b are disposed at the center in the Y-axis direction, and the second piezoelectric bodies 21a and 21b are disposed on both ends in the Y-axis direction. Gaps are provided between the second piezoelectric bodies 21a and 21b and the second piezoelectric bodies 22a and 22b. The piezoelectric driving element 1 has a structure symmetrical in the Y-axis direction.

A thickness D22 of each of the piezoelectric layers 222a and 222b of the second piezoelectric bodies 22a and 22b is smaller than a thickness D21 of each of the piezoelectric layers 212a and 212b of the second piezoelectric bodies 21a and 21b. The thicknesses of the respective electrode layers of the second piezoelectric bodies 21a, 21b, 22a, and 22b are equal to each other. Therefore, the thicknesses of the second piezoelectric bodies 22a and 22b are smaller than the thicknesses of the second piezoelectric bodies 21a and 21b. The configurations of the first piezoelectric bodies 10a and 10b are the same as in Embodiment 2.

The central second piezoelectric bodies 22a and 22b can be formed by a sputtering method using a metal mask, as in the modification in FIG. 7B. In this case as well, first, the central second piezoelectric bodies 22a and 22b are formed on the upper and lower surfaces of the shim material 30, and then a structure composed of the first piezoelectric bodies 10a and 10b and a structure composed of the second piezoelectric bodies 21a and 21b are bonded to the upper and lower surfaces of the shim material 30.

### Effects of Embodiment 3

In Embodiment 3 as well, as in Embodiments 1 and 2 described above, since the thicknesses of the second piezoelectric bodies 21a, 21b, 22a, and 22b are smaller than the thicknesses of the first piezoelectric bodies 10a and 10b, the resonance frequency of the element can be increased while the amount of displacement of and the generated force at the free end E2 are kept large.

Also, in Embodiment 3 as well, as in Embodiment 2, the second piezoelectric bodies 22a and 22b can be used for detecting strain of the free end E2. In this case, in Embodiment 3, the second piezoelectric bodies 21a and 21b for driving extend from the free end E2 to the vicinity of the boundary of the first piezoelectric bodies 10a and 10b, and the second piezoelectric bodies 21a and 21b are formed continuously in the X-axis direction from the fixed end E1 to the free end E2 while having a slight distance from the first piezoelectric bodies 10a and 10b. Therefore, as compared to Embodiment 2, the amount of displacement and the force generated by the second piezoelectric bodies 21a and 21b can be increased. In addition, the second piezoelectric bodies 22a and 22b for strain detection extend from the vicinity of the boundary of the first piezoelectric bodies 10a and 10b to the distal end of the piezoelectric driving element 1 in the X-axis direction in which a change in the amount of bending is larger than in Embodiment 2, and driving parts composed of the second piezoelectric bodies 21a and 21b are also formed at positions, near the second piezoelectric bodies 22a and 22b, aligned in the direction (Y-axis direction) intersecting the direction from the fixed end E1 toward the free end E2. Therefore, the amount of electric charge detected by the second piezoelectric bodies 22a and 22b is increased, so that strain corresponding to the amount of displacement of the free end E2 can be monitored more accurately.

Also, as shown in FIG. 8 and FIGS. 9A and 9B, the second piezoelectric bodies 21a and 21b for driving the free end E2 are disposed in regions symmetrical in the direction (Y-axis direction) perpendicular to the direction (X-axis direction) from the fixed end E1 toward the free end E2. Accordingly, the free end E2 can be uniformly driven by the second piezoelectric bodies 21a and 21b for driving, so that twisting of the free end E2 can be suppressed.

In addition, as shown in FIG. 8 and FIGS. 9A and 9B, the second piezoelectric bodies 22a and 22b for detecting strain of the free end E2 are disposed in the regions symmetrical in the direction (Y-axis direction) perpendicular to the direction (X-axis direction) from the fixed end E1 toward the free end E2. Since the second piezoelectric bodies 22a and 22b are uniformly disposed, without being non-uniformly distributed on one side in the Y-axis direction, as described above, twisting in the bending of the free end E2 due to the second piezoelectric bodies 22a and 22b becoming unbalanced loads can be suppressed. Therefore, the free end E2 can be satisfactorily displaced by the second piezoelectric bodies 21a and 22a for driving while strain of the free end E2 is detected by the second piezoelectric bodies 22a and 22b.

In the configuration in FIG. 8 to FIG. 10B, the second piezoelectric bodies 22a and 22b for strain detection are disposed at the center in the Y-axis direction. However, the second piezoelectric bodies 21a and 21b for driving may be disposed at the center in the Y-axis direction, and the second piezoelectric bodies 22a and 22b for strain detection may be disposed on both sides in the Y-axis direction.

Also, in the configuration in FIG. 8 to FIG. 10B, the thicknesses of the second piezoelectric bodies 22a and 22b for detection are smaller than the thicknesses of the second piezoelectric bodies 21a and 21b for driving. However, as in the case of FIG. 5 and FIGS. 6A and 6B, the thicknesses of the second piezoelectric bodies 22a and 22b for detection may be equal to the thicknesses of the second piezoelectric bodies 21a and 21b for driving.

Also, in the configuration in FIG. 8 to FIG. 10B, the length of the second piezoelectric body 21a and the length of the second piezoelectric body 22a are equal to each other. However, the length of the second piezoelectric body 21a may be different from the length of the second piezoelectric body 22a.

### Embodiment 4

In Embodiment 1 described above, the first piezoelectric bodies 10a and 10b and the second piezoelectric bodies 20a and 20b are disposed on the upper and lower surfaces of the shim material 30, but a first piezoelectric body and a second piezoelectric body may be disposed on only one of the upper and lower surfaces of the shim material 30.

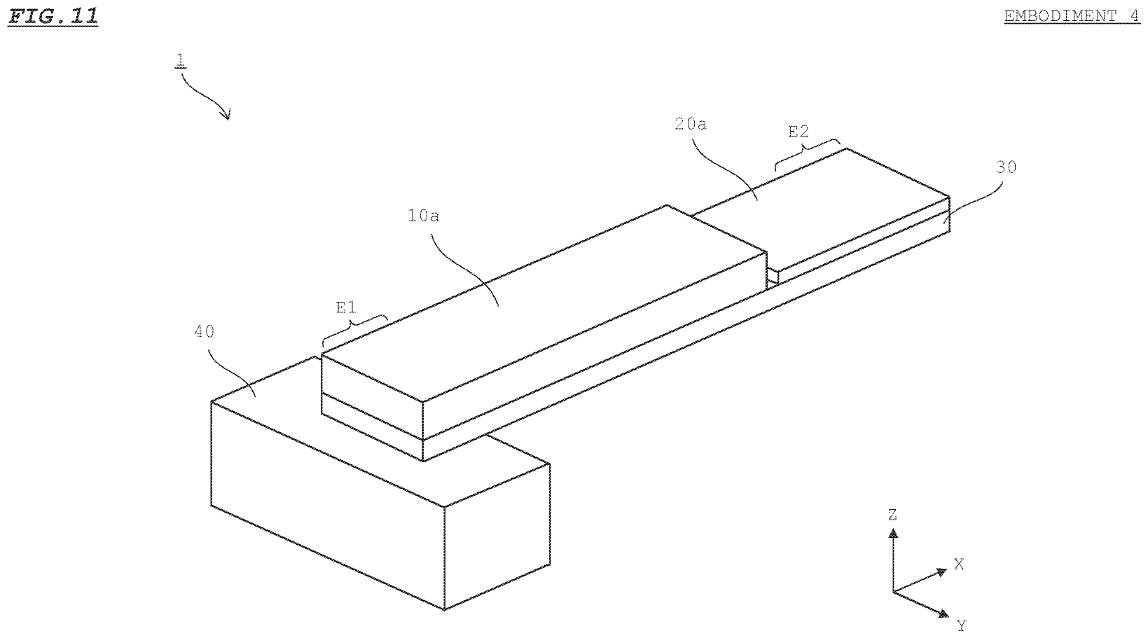

FIG. 11 is a perspective view showing a configuration of the piezoelectric driving element 1 according to Embodiment 4.

In the configuration example in FIG. 11, the first piezoelectric body 10a and the second piezoelectric body 20a are disposed on only the upper surface of the shim material 30. The configurations of the first piezoelectric body 10a and the second piezoelectric body 20a are the same as in Embodiment 1. The first piezoelectric body 10a and the second piezoelectric body 20a are disposed on the upper surface of the shim material 30, for example, through the same process as in FIGS. 3A to 3D. In the configuration example in FIG. 11, after the first piezoelectric body 10a and the second piezoelectric body 20a are disposed on the upper surface of the shim material 30, an end portion on the fixed end E1 side of the shim material 30 is bonded to the support base 40.

When a driving voltage is applied to the first piezoelectric body 10a and the second piezoelectric body 20a, the first piezoelectric body 10a and the second piezoelectric body 20a expand and contract in the longitudinal direction (X-axis direction). At this time, the expansion and contraction of the first piezoelectric body 10a and the second piezoelectric body 20a near the surfaces of the first piezoelectric body 10a and the second piezoelectric body 20a to which the shim material 30 is bonded is reduced by being restrained by the shim material 30, but the expansion and contraction of the first piezoelectric body 10a and the second piezoelectric body 20a near the surfaces of the first piezoelectric body 10a and the second piezoelectric body 20a that are opposite to the surfaces to which the shim material 30 is bonded is increased. Therefore, when the first piezoelectric body 10a and the second piezoelectric body 20a expand and contract in the longitudinal direction (X-axis direction), the shim material 30 and also the free end E2 are displaced in the Z-axis direction. Accordingly, a to-be-driven body disposed at the free end E2 is driven.

### Effects of Embodiment 4

In Embodiment 4 as well, as in Embodiments 1 to 3 described above, since the thickness of the second piezoelectric body 20a is smaller than the thickness of the first piezoelectric body 10a, the resonance frequency of the element can be increased while the amount of displacement of and the generated force at the free end E2 are kept large.

In the configuration example in FIG. 11, the first piezoelectric body 10a and the second piezoelectric body 20a are disposed on only the upper surface of the shim material 30. However, the first piezoelectric body 10a and the second piezoelectric body 20a may be omitted from the configuration in FIG. 1, and the first piezoelectric body 10b and the second piezoelectric body 20b may be disposed on only the lower surface of the shim material 30.

In the configuration in FIG. 11, since the first piezoelectric body 10a and the second piezoelectric body 20a are disposed on only one surface of the shim material 30, the driving force is decreased as compared to that in the case where the first piezoelectric bodies 10a and 10b and the second piezoelectric bodies 20a and 20b are disposed on both surfaces of the shim material 30 as in Embodiment 1 described above. Therefore, in order to increase the amount of displacement of the free end E2 by exerting a larger generated force on the free end E2, the first piezoelectric body and the second piezoelectric body are preferably disposed above and below a flat surface from the fixed end E1 toward the free end E2 (on the upper and lower surfaces of the shim material 30), respectively, as in Embodiment 1 described above.

### Embodiment 5

In Embodiment 5, the second piezoelectric body 20a in the configuration in Embodiment 4 is further divided into a plurality of parts.

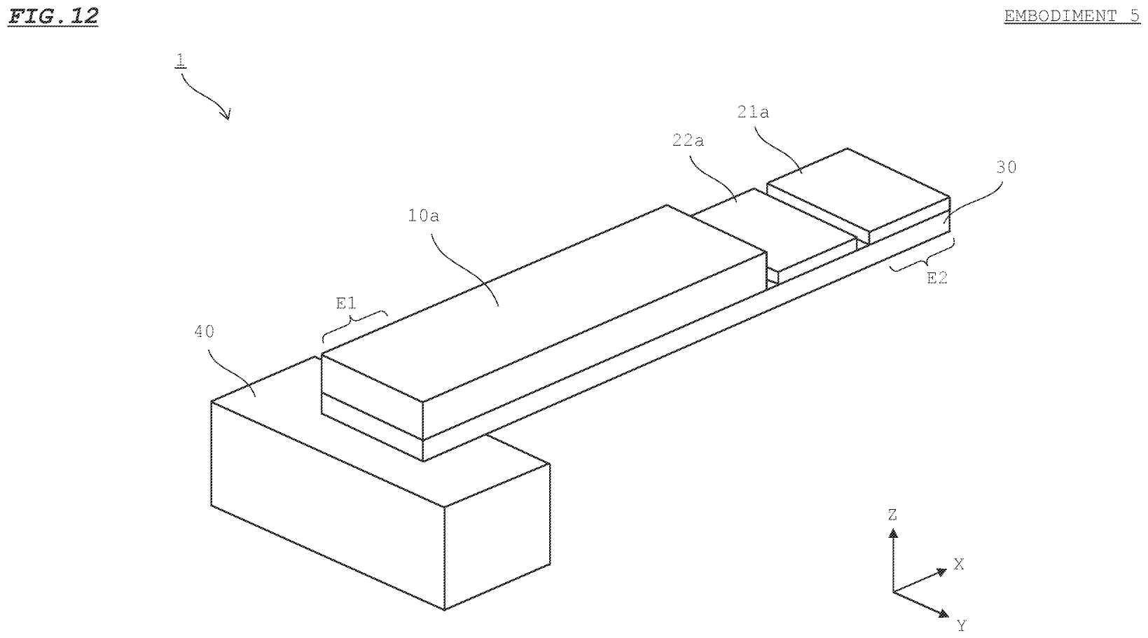

FIG. 12 is a perspective view showing a configuration of the piezoelectric driving element 1 according to Embodiment 5.

In the configuration of FIG. 12, the second piezoelectric body is divided in the X-axis direction. The second piezoelectric bodies 21a and 22a are disposed so as to be aligned in the direction (X-axis direction) from the fixed end E1 toward the free end E2. The piezoelectric driving element 1 in FIG. 12 has a configuration in which the first piezoelectric body 10b and the second piezoelectric bodies 22a and 22b on the lower side are omitted from the piezoelectric driving element 1 of Embodiment 2 shown in FIG. 5 to FIG. 6B. In this configuration as well, after the first piezoelectric body 10a and the second piezoelectric body 20a are disposed on the upper surface of the shim material 30, the end portion on the fixed end E1 side of the shim material 30 is bonded to the support base 40.

In the configuration in FIG. 12 as well, as in Embodiment 2, the second piezoelectric body 22a can be used for detecting strain of the free end E2. As in the case of FIG. 7B, the thickness of the second piezoelectric body 22a may be smaller than the thickness of the second piezoelectric body 21a. In addition, as in the case of FIG. 7A, the width of the second piezoelectric body 22a may be smaller than the width of the second piezoelectric body 21a, and second piezoelectric bodies for driving may be further disposed in the regions shown by the broken lines in FIG. 7A.

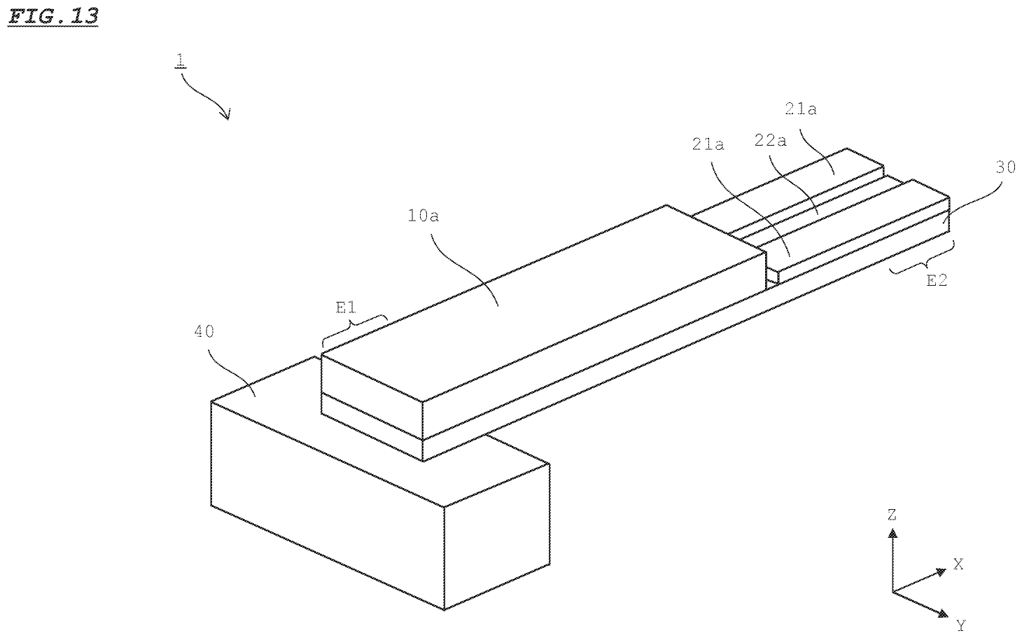

FIG. 13 is a perspective view showing another configuration of the piezoelectric driving element 1 according to Embodiment 5.

In the configuration in FIG. 13, two second piezoelectric bodies 21a and a second piezoelectric body 22a are disposed so as to be aligned in the direction (Y-axis direction) intersecting the direction from the fixed end E1 toward the free end E2. The second piezoelectric body 22a is disposed at the center in the Y-axis direction, and the two second piezoelectric bodies 21a are disposed on both sides in the Y-axis direction. The thickness of the central second piezoelectric body 22a is smaller than the thickness of each of the second piezoelectric bodies 21a on both sides.

The piezoelectric driving element 1 in FIG. 13 has a configuration in which the first piezoelectric body 10b and the second piezoelectric bodies 22a and 22b are omitted from the piezoelectric driving element 1 of Embodiment 3 shown in FIG. 8 to FIG. 10B. In this configuration as well, after the first piezoelectric body 10a and the second piezoelectric body 20a are disposed on the upper surface of the shim material 30, the end portion on the fixed end E1 side of the shim material 30 is bonded to the support base 40.

In the configuration in FIG. 13 as well, as in Embodiment 3 described above, the second piezoelectric body 22a can be used for detecting strain of the free end E2. As in the case of Embodiment 3 described above, the thickness of the second piezoelectric body 22a may be equal to the thickness of each second piezoelectric body 21a. In addition, as in the case of Embodiment 3 described above, the second piezoelectric body 21a for driving may be disposed at the center in the Y-axis direction, and the second piezoelectric body 22a for strain detection may be disposed on each of both sides in the Y-axis direction. The length of each second piezoelectric body 21a and the length of the second piezoelectric body 22a may be different from each other.

In the configuration examples in FIG. 12 and FIG. 13, as in the configuration example in FIG. 11, when a voltage is applied to the first piezoelectric body 10a and each second piezoelectric body 21a, the expansion and contraction of the first piezoelectric body 10a and the second piezoelectric body 21a near the surfaces of the first piezoelectric body 10a and the second piezoelectric body 21a to which the shim material 30 is bonded is different from that near the surfaces of the first piezoelectric body 10a and the second piezoelectric body 21a that are opposite to the surfaces to which the shim material 30 is bonded, whereby the shim material 30 and also the free end E2 are displaced in the Z-axis direction. Accordingly, a to-be-driven body disposed at the free end E2 is driven. At this time, the electric charge corresponding to the amount of displacement of the free end E2 can be detected using the second piezoelectric body 22a. Accordingly, feedback control for displacing the free end E2 by a target displacement amount is performed. In the configuration in FIG. 13, the second piezoelectric body 22a for strain detection extends from the vicinity of the boundary of the first piezoelectric body 10a to the distal end of the piezoelectric driving element 1 in the X-axis direction in which a change in the amount of bending is larger than in the configuration in FIG. 12, and driving parts composed of the second piezoelectric bodies 21a are also formed at positions, near the second piezoelectric body 22a, aligned in the direction (Y-axis direction) intersecting the direction from the fixed end E1 toward the free end E2. Therefore, the amount of electric charge detected by the second piezoelectric body 22a is increased, so that the amount of strain corresponding to the amount of displacement of the free end E2 can be monitored more accurately.

### Effects of Embodiment 5

In Embodiment 5 as well, as in Embodiments 1 to 4 described above, since the thicknesses of the second piezoelectric bodies 21a and 22a are smaller than the thickness of the first piezoelectric body 10a, the resonance frequency of the element can be increased while the amount of displacement of and the generated force at the free end E2 are kept large.

In addition, by using the second piezoelectric body 22a for detecting displacement of the free end E2, feedback control can be performed such that the amount of displacement of the free end E2 becomes a target displacement amount, while the generated force at the free end E2 is compensated for by the second piezoelectric body 21a.

In the configurations in FIG. 12 and FIG. 13, since the first piezoelectric body 10a and the second piezoelectric bodies 21a and 22a are disposed on only one surface of the shim material 30, the driving force is decreased as compared to that in the case where the first piezoelectric bodies 10a and 10b and the second piezoelectric bodies 21a, 21b, 22a, and 22b are disposed on both surfaces of the shim material 30 as in Embodiments 2 and 3. Therefore, in order to increase the amount of displacement of the free end E2 by exerting a larger generated force on the free end E2, the first piezoelectric body and the second piezoelectric body are preferably disposed above and below a flat surface from the fixed end E1 toward the free end E2 (on the upper and lower surfaces of the shim material 30), respectively, as in Embodiment 1 described above.

### Embodiment 6

In Embodiments 1 to 3 described above, the first piezoelectric bodies 10a and 10b and the second piezoelectric bodies 21a, 21b, 22a, and 22b are disposed on the upper and lower surfaces of the shim material 30. However, in Embodiment 6, the shim material 30 is omitted.

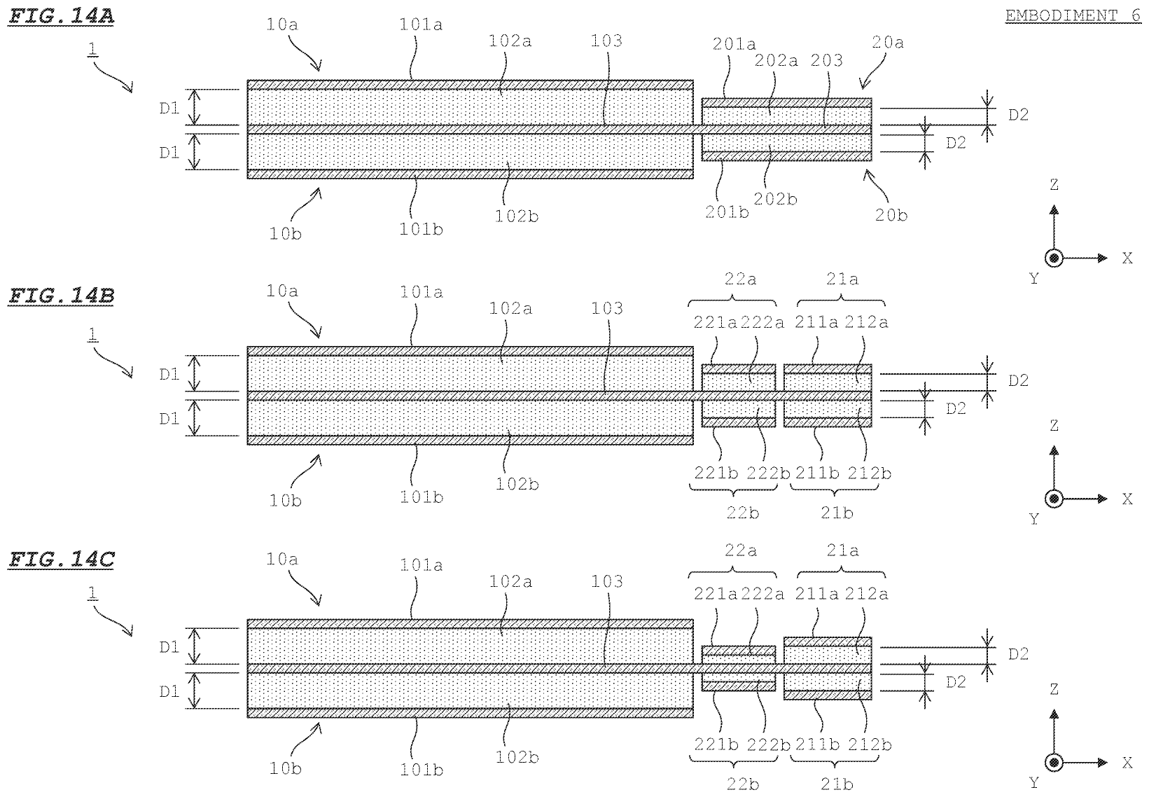

FIG. 14A is a cross-sectional view showing a configuration of the piezoelectric driving element 1 in which the shim material 30 is omitted from the configuration of Embodiment 1 shown in FIG. 1 to FIG. 2B. FIG. 14A shows a cross-sectional view of a structure of the piezoelectric driving element 1 excluding the support base 40, taken at the center position in the Y-axis direction along a plane parallel to the X-Z plane.

FIG. 14B is a cross-sectional view showing a configuration of the piezoelectric driving element 1 in which the shim material 30 is omitted from the configuration of Embodiment 2 shown in FIG. 5 to FIG. 6B. FIG. 14B shows a cross-sectional view of a structure of the piezoelectric driving element 1 excluding the support base 40, taken at the center position in the Y-axis direction along a plane parallel to the X-Z plane.

FIG. 14C is a cross-sectional view showing a configuration of the piezoelectric driving element 1 in which the shim material 30 is omitted from the configuration of the modification of Embodiment 2 shown in FIG. 7B. FIG. 14C shows a cross-sectional view of a structure of the piezoelectric driving element 1 excluding the support base 40, taken at the center position in the Y-axis direction along a plane parallel to the X-Z plane.

In the configuration of FIG. 14A, an electrode layer 103 is shared by the first piezoelectric bodies 10a and 10b and the second piezoelectric bodies 20a and 20b, and in the configurations in FIGS. 14B and 14C, an electrode layer 103 is shared by the first piezoelectric bodies 10a and 10b and the second piezoelectric bodies 21a, 21b, 22a, and 22b. The shared electrode layer 103 is connected to a ground, and a driving voltage is applied to the electrode layers 101a, 101b, 201a, 201b, 211a, and 211b. At this time, in the case where the polarization directions of the respective piezoelectric layers 102a, 202a, and 212a of the first piezoelectric bodies 10a, 20a, and 21a and the respective piezoelectric layers 102b, 202b, and 212b of the second piezoelectric bodies 10b, 20b, and 21b are made to be substantially the same on the positive and negative sides in the Z-axis direction, expansion of the first piezoelectric bodies 10a, 20a, and 21a and contraction of the second piezoelectric bodies 10b, 20b, and 21b, or contraction of the first piezoelectric bodies 10a, 20a, and 21a and expansion of the second piezoelectric bodies 10b, 20b, and 21b can be simultaneously caused by applying a voltage having a phase opposite to that of the ground potential of the electrode layer 103, to the electrode layers 101a, 201a, and 211a and the electrode layers 101b, 201b, and 211b. On the other hand, in the case where the polarization directions of the respective piezoelectric layers 102a, 202a, and 212a of the first piezoelectric bodies 10a, 20a, and 21a and the respective piezoelectric layers 102b, 202b, and 212b of the second piezoelectric bodies 10b, 20b, and 21b are made to be substantially opposite to each other on the positive and negative sides in the Z-axis direction, expansion of the first piezoelectric bodies 10a, 20a, and 21a and contraction of the second piezoelectric bodies 10b, 20b, and 21b, or contraction of the first piezoelectric bodies 10a, 20a, and 21a and expansion of the second piezoelectric bodies 10b, 20b, and 21b can be simultaneously caused by applying a voltage having the same phase as the ground potential of the electrode layer 103, to the electrode layers 101a, 201a, and 211a and the electrode layers 101b, 201b, and 211b. Here, the polarization directions of the respective piezoelectric layers 102a, 202a, and 212a of the first piezoelectric bodies 10a, 20a, and 21a and the respective piezoelectric layers 102b, 202b, and 212b of the second piezoelectric bodies 10b, 20b, and 21b are determined by the polarity of a voltage during a polarization treatment including a step of applying in advance a voltage, which is higher than the driving voltage to be used, between the electrode layer 103 and each of the electrode layers 101a, 101b, 201a, 201b, 211a, and 211b after the piezoelectric driving element 1 is produced. The free end E2 is displaced in the Z-axis direction by such expansion and contraction in the longitudinal direction (X-axis direction) of the upper and lower first piezoelectric bodies 10a and 10b and the upper and lower second piezoelectric bodies 20a and 20b or the upper and lower first piezoelectric bodies 10a and 10b and the upper and lower second piezoelectric bodies 21a and 21b.

Also, in the configurations in FIGS. 14B and 14C, the second piezoelectric bodies 22a and 22b can be used as detection elements for monitoring the amount of strain corresponding to the amount of displacement of the free end E2. In this case, in the configuration in FIG. 14C, the thicknesses of the second piezoelectric bodies 22a and 22b (the thicknesses of the piezoelectric layers 222a and 222b) are smaller than those in the configuration in FIG. 14B, so that the resonance frequency of the element can be increased while the ability to detect an amount of strain is ensured.

The piezoelectric driving element 1 shown in FIG. 14A is formed, for example, as follows.

The Ag electrodes 401 and 402 are formed by printing on only one surfaces of the PZT thin plates 301 and 302 formed by the same method as in FIG. 3A. Next, the PZT thin plates 301 and 302 having the Ag electrodes 401 and 402 printed on the surfaces thereof are diced into individual pieces. The thus-individualized structures are bonded to the upper and lower surfaces of a conductive plate composed of a copper plate or the like. Accordingly, the structure in FIG. 14A is formed.

The PZT thin plate 301 and the PZT thin plate 302 correspond to the piezoelectric layers 102a and 102b and the piezoelectric layers 202a and 202b in FIG. 14A, respectively, and the Ag electrode 401 and the Ag electrode 402 correspond to the electrode layers 101a and 101b and the electrode layers 201a and 201b in FIG. 14A, respectively. In addition, the conductive plate corresponds to the electrode layer 103 in FIG. 14A. As described above, the electrode layer 103 is shared by the first piezoelectric bodies 10a and 10b and the second piezoelectric bodies 20a and 20b.

In FIGS. 14B and 14C as well, the structures composed of the first piezoelectric bodies 10a and 10b and the second piezoelectric bodies 21a, 21b, 22a, and 22b formed by the same method are bonded to the upper and lower surfaces of the shared electrode layer 103 which is composed of a conductive plate, whereby the piezoelectric driving element 1 is formed. In the configuration in FIG. 14C, as in the case of FIG. 7B, the second piezoelectric bodies 22a and 22b may be formed by a sputtering method using a metal mask.

### Effects of Embodiment 6

In Embodiment 6 as well, as in Embodiments 1 to 5 described above, since the thicknesses of the second piezoelectric bodies 21a, 21b, 22a, and 22b are smaller than the thicknesses of the first piezoelectric bodies 10a and 10b, the resonance frequency of the element can be increased while the amount of displacement of and the generated force at the free end E2 are kept large.

In addition, by using the second piezoelectric body 22a for detecting strain corresponding to the amount of displacement of the free end E2, feedback control can be performed such that the amount of displacement of the free end E2 becomes a target displacement amount, while the generated force at the free end E2 is compensated for by the second piezoelectric bodies 21a and 21b.

In the above, the configurations in which the shim material 30 is omitted from the configurations of Embodiment 1, Embodiment 2, and the modifications of Embodiment 2 are shown, but the piezoelectric driving element 1 may be configured by omitting the shim material 30 from the configuration of Embodiment 3 shown in FIG. 8 to FIG. 10B. In this case as well, the same effects as described above can be achieved.

### Other Modifications

In Embodiments 1 to 6 described above, gaps are provided between the first piezoelectric bodies 10a and 10b and the second piezoelectric bodies 20a, 20b, 21a, 21b, 22a, and 22b, but the piezoelectric layers of the first piezoelectric bodies 10a and 10b and the piezoelectric layers of the second piezoelectric bodies 20a, 20b, 21a, 21b, 22a, and 22b may be connected to each other.

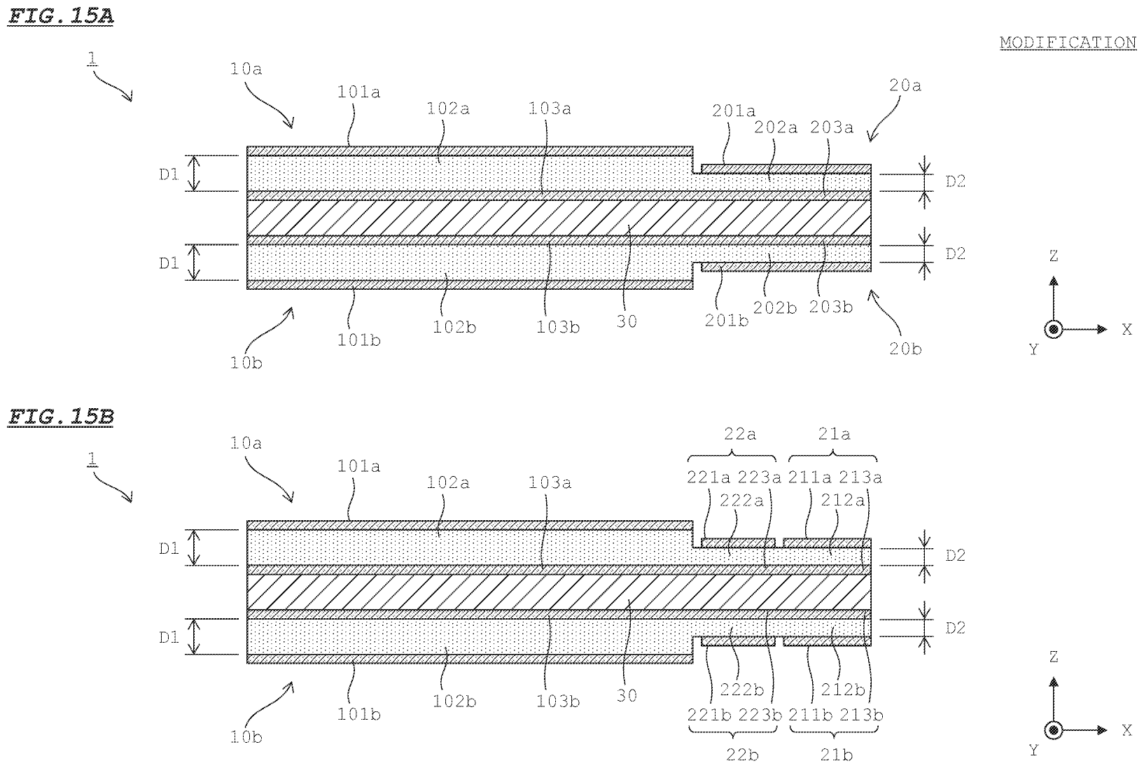

FIG. 15A is a diagram showing a configuration example in which in the configuration of Embodiment 1, the piezoelectric layer 102a and the piezoelectric layer 202a are connected to each other and the piezoelectric layer 102b and the piezoelectric layer 202b are connected to each other. FIG. 15B is a diagram showing a configuration example in which in the configuration of Embodiment 2, the piezoelectric layer 102a, the piezoelectric layer 222a, and the piezoelectric layer 212a are connected to each other and the piezoelectric layer 102b, the piezoelectric layer 222b, and the piezoelectric layer 212b are connected to each other.

In these configuration examples as well, the thickness D2 of each of the piezoelectric layers 212a, 212b, 222a, and 222b is smaller than the thickness D1 of each of the piezoelectric layers 102a and 102b. In addition, the electrodes on the surface side of the first piezoelectric bodies 10a and 10b and the electrodes on the surface side of the second piezoelectric bodies 20a, 20b, 21a, 21b, 22a, and 22b are separated from each other. The electrodes on the shim material 30 side of the first piezoelectric bodies 10a and 10b and the electrodes on the shim material 30 side of the second piezoelectric bodies 20a, 20b, 21a, 21b, 22a, and 22b may be shared as shown in FIGS. 15A and 15B.

In the configurations in FIGS. 15A and 15B as well, by connecting the shared electrode layers 103a and 103b to a ground and applying a driving voltage to the electrode layers 101a, 101b, 201a, 201b, 211a, and 211b on the surface side, the free end E2 can be displaced. Also, in the configuration in FIG. 15B, the second piezoelectric bodies 22a and 22b can be used for detecting the amount of strain corresponding to the amount of displacement of the free end E2.

In the embodiments and the modifications other than Embodiments 1 and 2 as well, similarly, the piezoelectric layers of the first piezoelectric bodies 10a and 10b and the piezoelectric layers of the second piezoelectric bodies 20a, 20b, 21a, 21b, 22a, and 22b may be connected to each other.

In Embodiments 2, 3, and 5 described above, the second piezoelectric bodies 22a and 22b are used for detecting the amount of strain corresponding to the amount of displacement of the free end E2, but both or either one of these piezoelectric bodies may be used for driving the free end E2. In the configurations of Embodiment 6 shown in FIGS. 14B and 14C and the configuration of the modification shown in FIG. 15B as well, both or either one of the second piezoelectric bodies 22a and 22b may be used for driving the free end E2.

In Embodiments 1 to 6 and the modifications described above, the first piezoelectric bodies 10a and 10b are integrally formed, but the first piezoelectric bodies 10a and 10b may each be divided into a plurality of parts in the length direction (X-axis direction) or the width direction (Y-axis direction).

The number of parts into which the second piezoelectric body is divided is not limited to the numbers shown in Embodiments 2, 3, 5, and 6 described above, and the second piezoelectric body may be divided into another number of parts.

The size and the material of each part of the piezoelectric driving element 1 and the manufacturing method for the piezoelectric driving element 1 are not limited to those shown in Embodiments 1 to 6 and the modifications described above, and can be changed as appropriate.

In addition to the above, various modifications can be made as appropriate to the embodiments of the present invention, without departing from the scope of the technological idea defined by the claims.

What is claimed is:

1. A cantilever-type piezoelectric driving element in which one end which is a fixed end is fixed to a support base and another end which is a free end is driven, the piezoelectric driving element comprising:
a first piezoelectric body disposed on the fixed end side; and
a second piezoelectric body disposed on the free end side with respect to the fixed end, wherein
a thickness of the second piezoelectric body is smaller than a thickness of the first piezoelectric body.

2. The piezoelectric driving element according to claim 1, wherein the second piezoelectric body is divided into a plurality of second piezoelectric bodies.

3. The piezoelectric driving element according to claim 2, wherein the plurality of divided second piezoelectric bodies are aligned in a direction from the fixed end toward the free end.

4. The piezoelectric driving element according to claim 2, wherein the plurality of divided second piezoelectric bodies are aligned in a direction intersecting a direction from the fixed end toward the free end.

5. The piezoelectric driving element according to claim 2, wherein a thickness of one of the plurality of divided second piezoelectric bodies is smaller than a thickness of another one(s) of the plurality of divided second piezoelectric bodies.

6. The piezoelectric driving element according to claim 2, wherein the plurality of second piezoelectric bodies are classified into a piezoelectric body for driving the free end and a piezoelectric body for detecting strain of the free end.

7. The piezoelectric driving element according to claim 6, wherein a thickness of the second piezoelectric body for detecting strain of the free end is smaller than a thickness of the second piezoelectric body for driving the free end.

8. The piezoelectric driving element according to claim 6, wherein the second piezoelectric body for driving the free end is disposed in each of regions symmetrical in a direction perpendicular to a direction from the fixed end toward the free end.

9. The piezoelectric driving element according to claim 6, wherein the second piezoelectric body for detecting strain of the free end is disposed in each of regions symmetrical in a direction perpendicular to a direction from the fixed end toward the free end.

10. The piezoelectric driving element according to claim 1, wherein the first piezoelectric body and the second piezoelectric body are disposed so as to be overlaid on a plate-shaped shim material.

11. The piezoelectric driving element according to claim 1, wherein the first piezoelectric body and the second piezoelectric body are disposed above and below a flat surface from the fixed end toward the free end.
